(19) United States
(12) Patent Application Publication
(10) Pub. No.: US 2014/0175499 A1
(43) Pub. Date: Jun. 26, 2014

(54) LIGHT EMITTING DIODE

(71) Applicant: Hon Hai Precision Industry Co., Ltd., New Taipei (TW)

(72) Inventor: CHIH-CHEN LAI, New Taipei (TW)

(73) Assignee: HON HAI PRECISION INDUSTRY CO., LTD., New Taipei (TW)

(21) Appl. No.: 14/011,686

(22) Filed: Aug. 27, 2013

(30) Foreign Application Priority Data
Dec. 24, 2012 (TW) 101149444

(51) Int. Cl. H01L 33/62

(52) U.S. Cl. CPC H01L 33/62
USPC 257/99

(57) ABSTRACT

An LED includes an LED chip, a substrate, a first electrode and a second electrode formed on the LED chip, and a first solder layer and a second solder layer formed on a top face of the substrate. The first solder layer is soldered on the first electrode and sandwiched between the LED chip and the substrate. The second solder layer is soldered on the second electrode and sandwiched between the LED chip and the substrate. A projection of the first solder layer on the top face of the substrate exceeds a periphery of a projection of the LED chip on the top face of the substrate. A projection of the second solder layer on the top face of the substrate exceeds the periphery of the projection of the LED chip on the top face of the substrate.

### BACKGROUND

1. Technical Field

The disclosure relates to light emitting diodes (LEDs), and particularly to a flip-chip light emitting diode with a strengthened solder structure.

2. Description of the Related Art

A conventional light emitting diode (LED) commonly includes a substrate and an LED chip soldered on the substrate. A first electrode and a second electrode are formed on a bottom face of the LED chip. A first solder layer and a second solder layer are formed on a top face of the substrate. The first solder layer is soldered on the first electrode and sandwiched between the LED chip and the substrate. The second solder layer is soldered on the second electrode and sandwiched between the LED chip and the substrate. However, the LED chip is prone to tilting relative to the substrate or even disengaging from the substrate when subjected to shock or vibration during manufacturing of the conventional LED.

Therefore, it is desirable to provide a light emitting diode which can overcome the above-described shortcomings.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting diode and a method for manufacturing the light emitting diode.

Moreover, in the drawings, like reference numerals designate corresponding parts throughout the views.

FIG. 1 is an isometric, cross-sectional view of a light emitting diode in accordance with an embodiment of the present disclosure.

FIG. 2 is a top plan view of the light emitting diode of FIG. 1.

### DETAILED DESCRIPTION

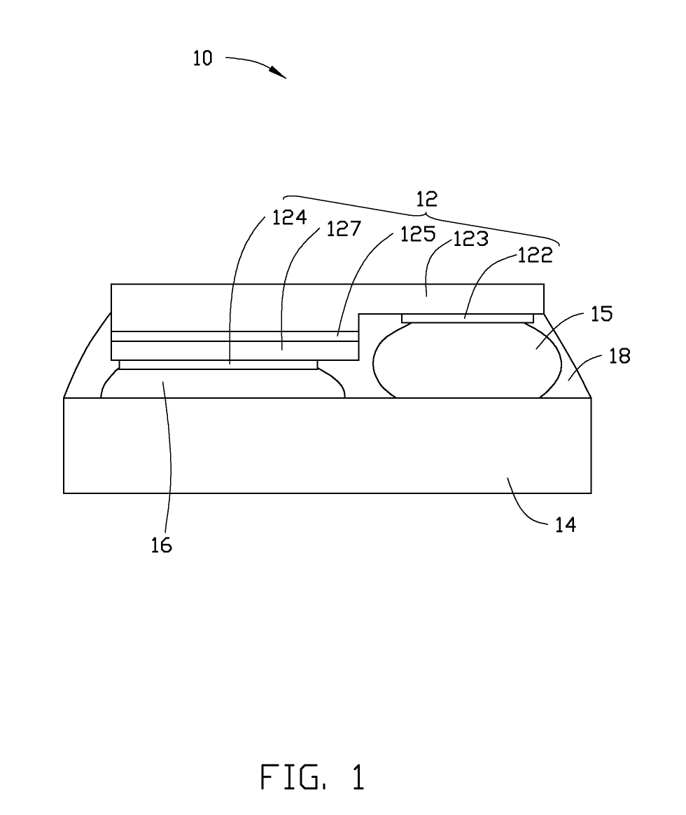

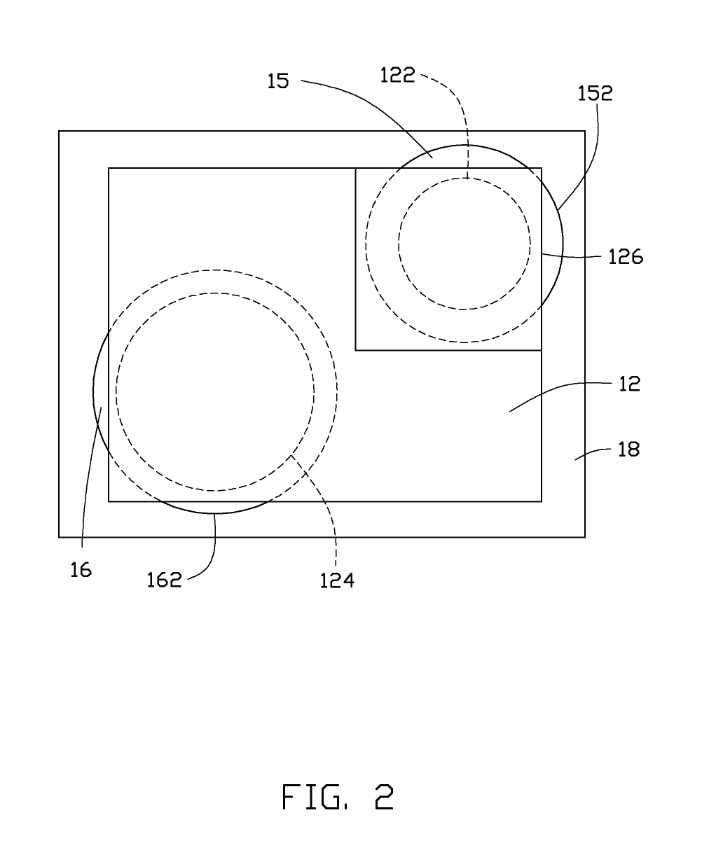

Referring to FIGS. 1-2, an LED 10 in accordance with an exemplary embodiment of the present disclosure is provided. The LED 10 includes an LED chip 12, a rectangular substrate 14, a first solder layer 15, a second solder layer 16, and an underfill adhesive 18.

The LED chip 12 includes a first semiconductor layer 123, an active layer 125 and a second semiconductor layer 127 stacked in sequence along a height direction. The active layer 125 is sandwiched between the first semiconductor layer 123 and the second semiconductor layer 127. The first semiconductor layer 123 and the second semiconductor layer 127 are doped with different materials. In this embodiment, the first semiconductor layer 123 is N-type doped, and the second semiconductor layer 127 is P-type doped. In an alternative embodiment, the first semiconductor layer 123 is P-type doped, and the second semiconductor layer 127 is

N-type doped. The active layer 125 can be a single quantum well (SQW) structure or a multiple quantum well (MQW) structure.

A first electrode 122 is formed on a bottom face of the first semiconductor layer 123. A second electrode 124 is formed on a bottom face of the second semiconductor layer 127. A projection of the first electrode 122 on a top face of the substrate 14 is circular, and a projection of the second electrode 124 on the top face of the substrate 14 is also circular.

The substrate 14 is a plastic plate or a ceramic plate, such as an alumina plate, a zinc oxide plate or a silicon plate, with electrical wires formed on its top face.

The first solder layer 15 and the second solder layer 16 are spaced from each other, and formed on diagonal positions of the top face of the substrate 14, respectively. Each of the first solder layer 15 and the second solder layer 16 has a circular projection on the top face of the substrate 14. The first solder layer 15 is soldered on the first electrode 122 and sandwiched between the LED chip 12 and the top face of the substrate 14. The second solder layer 16 is soldered on the second electrode 124 and sandwiched between the LED chip 12 and the top face of the substrate 14. The projection of the first solder layer 15 on the top face of the substrate 14 has a portion exceeding (i.e., projecting outside of) a periphery of a projection of the LED chip 12 on the top face of the substrate 14. The projection of the second solder layer 16 on the top face of the substrate 14 has a portion exceeding (projecting outside of) the projection of the LED chip 12 on the top face of the substrate 14. That is, a part of outer border 152 of the first solder layer 15 and a part of outer border 162 of the second solder layer 16 exceed beyond an outer edge 126 of the LED chip 12 along a plane direction of the top face of the substrate 14, so that each of the first solder layer 15 and the second solder layer 16 have a large surface area.

The underfill adhesive 18 is made from, for example, a liquid alicyclic epoxy resin with low viscosity, a spherical silicon micro-powder, an epoxy hardener, a promoter, a surface treating agent for silicon micro-powder, and additives with other functions. The underfill adhesive 18 is filled in a gap formed between the LED chip 12 and the substrate 14, to reinforce a connecting strength between the LED chip 12, the first solder layer 15, the second solder layer 16, and the substrate 14. In addition, sealing the first solder layer 15 and the second solder layer 16 via the underfill adhesive 18 can prevent external humidity/moisture from reaching and corroding the first solder layer 15 and the second solder layer 16. A profile of the solidified underfill adhesive 18 as viewed from a top of the LED 10 is a rectangular annulus or at least a portion of a rectangular annulus. An outer edge at a bottom of the underfill adhesive 18 is aligned with an outer edge of the substrate 14. An inner edge at a top of the underfill adhesive 18 contacts with a circumferential periphery of the LED chip 12.

Referring particularly to FIG. 2, in the LED 10 of the present disclosure, since the projection of the first solder layer 15 on the top face of the substrate 14 exceeds the periphery of the projection of the LED chip 12 on the top face of the substrate 14, and the projection of the second solder layer 16 on the top face of the substrate 14 exceeds the periphery of the projection of the LED chip 12 on the top face of the substrate 14, a connecting area of the LED chip 12 to the substrate 14 is thereby enhanced, whereby a support of the substrate 14 to the LED chip 12 is increased. Therefore, the structure of the LED 10 is strengthened, and the LED 10 will not deform easily and the LED chip 12 will not separate easily from the substrate 14 under an accidental force.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting diode, comprising:
an LED (light emitting diode) chip;
a substrate;
a first electrode and a second electrode formed on the LED chip; and
a first solder layer and a second solder layer formed on a top face of the substrate, the first solder layer being soldered on the first electrode and sandwiched between the LED chip and the substrate, the second solder layer being soldered on the second electrode and sandwiched between the LED chip and the substrate, a projection of the first solder layer on the top face of the substrate having at least a portion exceeding a periphery of a projection of the LED chip on the top face of the substrate, and a projection of the second solder layer on the top face of the substrate having at least a portion exceeding the periphery of the projection of the LED chip on the top face of the substrate.

2. The light emitting diode of claim 1, wherein the first solder layer and the second solder layer are spaced from each other, and formed on diagonal positions of the top face of the substrate, respectively.

3. The light emitting diode of claim 1, further comprising an underfill adhesive filled in a gap formed between the LED chip and the substrate.

4. The light emitting diode of claim 3, wherein a profile of the solidified underfill adhesive as viewed from a top of the light emitting diode is at least a portion of a rectangular annulus.

5. The light emitting diode of claim 3, wherein an outer edge at a bottom of the underfill adhesive is aligned with an outer edge of the substrate.

6. The light emitting diode of claim 5, wherein an inner edge at a top of the underfill adhesive contacts with a circumferential periphery of the LED chip.

7. The light emitting diode of claim 3, wherein the underfill adhesive is made from a liquid alicyclic epoxy resin with low viscosity, a spherical silicon micro-powder, an epoxy hardener, a promoter, and a surface treating agent for silicon micro-powder.

8. The light emitting diode of claim 1, wherein the LED chip comprises a first semiconductor layer, an active layer and a second semiconductor layer stacked in sequence, and the active layer is sandwiched between the first semiconductor layer and the second semiconductor layer.

9. The light emitting diode of claim 8, wherein the first electrode is formed on a bottom face of the first semiconductor layer, and the second electrode is formed on a bottom face of the second semiconductor layer.

10. The light emitting diode of claim 9, wherein a projection of the first electrode on a top face of the substrate is circular, and a projection of the second electrode on the top face of the substrate is also circular.

11. The light emitting diode of claim 8, wherein the first semiconductor layer and the second semiconductor layer are doped with different materials.

12. The light emitting diode of claim 11, wherein the first semiconductor layer is N-type doped, and the second semiconductor layer is P-type doped.

13. The light emitting diode of claim 11, wherein the first semiconductor layer is P-type doped, and the second semiconductor layer is N-type doped.

14. The light emitting diode of claim 8, wherein the active layer is a single quantum well structure or a multiple quantum well structure.

15. The light emitting diode of claim 1, wherein each of the first solder layer and the second solder layer has a circular projection on the top face of the substrate.

16. The light emitting diode of claim 1, wherein the substrate is a plastic plate or a ceramic plate with electrical wires formed on the top face thereof

17. The light emitting diode of claim 16, wherein the substrate is an alumina plate, a zinc oxide plate or a silicon plate.
